(19) United States
(12) Patent Application Publication
(10) Pub. No.: US 2024/0186406 A1
(43) Pub. Date: Jun. 6, 2024

(54) SEMICONDUCTOR DEVICE

(71) Applicant: Japan Display Inc., Tokyo (JP)

(72) Inventors: Hiroumi KINJO, Tokyo (JP); Masumi NISHIMURA, Tokyo (JP); Hayata AOKI, Tokyo (JP)

(73) Assignee: Japan Display Inc., Tokyo (JP)

(21) Appl. No.: 18/438,676

(22) Filed: Feb. 12, 2024

Related U.S. Application Data
(63) Continuation of application No. PCT/JP2022/031740, filed on Aug. 23, 2022.

(30) Foreign Application Priority Data
Sep. 7, 2021 (JP) 2021-145800

(51) Int. Cl. H01L 29/778; H01L 27/15; H01L 29/20; H01L 33/32; H01L 33/58

(52) U.S. Cl. CPC H01L 29/7786; H01L 27/15; H01L 29/2003; H01L 33/32; H01L 33/58

(57) ABSTRACT

A semiconductor device, which can provide semiconductor device using gallium nitride layer, includes an amorphous glass substrate, an oriented metal layer arranged above the amorphous glass substrate and having a crystal orientation, a first gallium nitride layer arranged above the oriented metal layer and having a first conductive type, a second gallium nitride layer arranged above the first gallium nitride layer, connected to the first gallium nitride layer, having higher conductive property than the first gallium nitride layer, including a source-side second gallium nitride layer and a drain-side second gallium nitride layer facing each other, and having a second conductive type, a gate electrode facing the first gallium nitride layer, and a gate insulating layer between the first gallium nitride layer and the gate electrode, wherein the gate insulating layer is positioned between the source-side second gallium nitride layer and the drain-side second gallium nitride layer in a cross-sectional view.

### CROSS REFERENCE TO RELATED APPLICATIONS

This application is a Continuation of International Patent Application No. PCT/JP2022/031740, filed on Aug. 23, 2022, which claims the benefit of priority to Japanese Patent Application No. 2021-145800 filed on Sep. 7, 2021, the entire contents of which are incorporated herein by reference.

### FIELD

An embodiment of the present invention relates to a semiconductor device using gallium nitride.

### BACKGROUND

Gallium nitride (GaN) is a direct-transition semiconductor with a large bandgap. A light-emitting diode (LED) including gallium nitride has been put into practical use by using the characteristics of gallium nitride. Gallium nitride is characterized by high electron saturation mobility and pressure resistance. In recent years, a transistor (semiconductor device) has been developed for use in a high-frequency power device or the like by utilizing the characteristics of gallium nitride. Generally, gallium nitride layers used in light-emitting diodes or transistors are deposited on sapphire substrates at high temperatures of 800° C. to 1000° C. using MOCVD (Metal Organic Chemical Vapor Deposition) or HVPE (Hydride Vapor Phase Epitaxy).

Furthermore, in recent years, so-called micro LED display devices or mini LED display devices in which small light-emitting diode chips are mounted in pixels of a circuit board have been developed as next-generation representative devices. The micro LED display devices or the mini LED display devices have high efficiency, high brightness, and high reliability. Such micro LED display devices or mini LED display devices are manufactured by transferring a LED tip to a backplane in which a transistor including low-temperature polysilicon, or an oxide semiconductor and the like is formed (for example, see U.S. Pat. No. 8,791,474). On the other hand, a method for forming a transistor including gallium nitride and a light-emitting diode on the same substrate has also been studied (see, for example, U.S. Patent Application Publication No. 2020/0075664).

### SUMMARY

A semiconductor device according to an embodiment of the present invention includes an amorphous glass substrate, an oriented metal layer arranged above the amorphous glass substrate and having a crystal orientation, a first gallium nitride layer arranged above the oriented metal layer and having a first conductive type, a second gallium nitride layer arranged above the first gallium nitride layer, connected to the first gallium nitride layer, having higher conductive property than the first gallium nitride layer, including a source-side second gallium nitride layer and a drain-side second gallium nitride layer facing each other, and having a second conductive type, a gate electrode facing the first gallium nitride layer, and a gate insulating layer between the first gallium nitride layer and the gate electrode, wherein the gate insulating layer is positioned between the source-side second gallium nitride layer and the drain-side second gallium nitride layer in a cross-sectional view.

A semiconductor device according to an embodiment of the present invention includes an amorphous glass substrate, an oriented metal layer arranged above the amorphous glass substrate, including a first oriented metal layer and a second oriented metal layer away from the first oriented metal layer, and having a crystal orientation, a first gallium nitride layer arranged above the oriented metal layer and having a first conductive type, a second gallium nitride layer arranged above the oriented metal layer, connected to the first gallium nitride layer, having higher conductive property than the first gallium nitride layer, including a source-side second gallium nitride layer and a drain-side second gallium nitride layer facing each other, and having a second conductive type, a gate electrode facing the first gallium nitride layer, and a gate insulating layer between the first gallium nitride layer and the gate electrode, wherein a portion separating the oriented metal layer and the second oriented metal layer crosses between the source-side second gallium nitride layer and the drain-side second gallium nitride layer in a cross-sectional view.

A semiconductor device according to an embodiment of the present invention includes an amorphous glass substrate, an oriented metal layer arranged above the amorphous glass substrate and having a crystal orientation, an oriented insulating layer arranged above the oriented metal layer, a first gallium nitride layer arranged above the oriented insulating layer and having a first conductive type, a second gallium nitride layer arranged above the oriented insulating layer, connected to the first gallium nitride layer, having higher conductive property than the first gallium nitride layer, including a source-side second gallium nitride layer and a drain-side second gallium nitride layer facing each other, and having a second conductive type, a gate electrode facing the first gallium nitride layer, and a gate insulating layer between the first gallium nitride layer and the gate electrode.

### BRIEF DESCRIPTION OF DRAWINGS

FIG. 1 is a cross-sectional view showing a configuration of a semiconductor device according to an embodiment of the present invention.

FIG. 2A is a cross-sectional view showing a configuration of a semiconductor device according to an embodiment of the present invention.

FIG. 2B is a plan view showing a configuration of a semiconductor device according to an embodiment of the present invention.

FIG. 3 is a cross-sectional view showing a configuration of a semiconductor device according to an embodiment of the present invention.

FIG. 4 is a cross-sectional view showing a configuration of a semiconductor device according to an embodiment of the present invention.

FIG. 5 is a cross-sectional view showing a configuration of a semiconductor device according to an embodiment of the present invention.

FIG. 6 is a cross-sectional view showing a configuration of a semiconductor device according to an embodiment of the present invention.

FIG. 7 is a cross-sectional view showing a configuration of a semiconductor device according to an embodiment of the present invention.

FIG. 8 is a cross-sectional view showing a configuration of a semiconductor device according to an embodiment of the present invention.

FIG. 9 is a cross-sectional view showing a configuration of a semiconductor device according to an embodiment of the present invention.

FIG. 10 is a cross-sectional view showing a configuration of a semiconductor device according to an embodiment of the present invention.

FIG. 11 is a cross-sectional view showing a configuration of a semiconductor device according to an embodiment of the present invention.

FIG. 12 is a schematic diagram showing a configuration of a display device according to an embodiment of the present invention.

FIG. 13 is a circuit diagram (pixel circuit) of a pixel of a display device according to an embodiment of the present invention.

FIG. 14 is a cross-sectional view of a pixel of a display device according to an embodiment of the present invention.

### DESCRIPTION OF EMBODIMENTS

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In the drawings, the widths, thicknesses, shapes, and the like of the respective portions may be schematically represented in comparison with actual embodiments for clarity of explanation. However, the shown shapes are merely examples, and do not limit the interpretation of the present invention. In the present specification and the drawings, elements similar to those described above with respect to the drawings described above are denoted by the same reference signs, and a detailed description thereof may be omitted as appropriate.

In each embodiment of the present invention, a direction from a substrate toward a gate electrode is referred to as “upper” or “above”. Conversely, a direction from the gate electrode toward the substrate is referred to as “lower” or “below”. As described above, although the term “above” or “below” is used to for convenience of explanation, for example, the substrate and the gate electrode may be arranged such that a vertical relationship between the substrate and the gate electrode is opposite to that shown in the drawing. In the following description, for example, the expression “gate electrode above the substrate” merely describes the vertical relationship between the substrate and the gate electrode as described above, and other members may be disposed between the substrate and the gate electrode. “Above” or “below” means a stacking order in a structure in which a plurality of layers are stacked, and in the case where the stacking order is expressed as a pixel electrode above the transistor, a positional relationship may be such that the transistor and the pixel electrode do not overlap each other in a plan view. On the other hand, the expression “pixel electrode vertically above the transistor” means a positional relationship in which the transistor and the pixel electrode overlap in a plan view.

As used herein, the phrase “a comprises A, B or C,” “a comprises any of A, B or C,” “a comprises one selected from the group consisting of A, B and C,” and the like does not exclude cases where a comprises a plurality of combinations of A to C unless otherwise indicated. Furthermore, these expressions do not exclude the case where a includes other elements.

The following embodiments can be combined with each other as long as there is no technical inconsistency.

Manufacturing methods of micro LED display devices by a transfer of LED tips have high manufacturing costs, and it is difficult to manufacture the micro LED display devices at low cost. If a transistor using gallium nitride can be formed together with a light-emitting diode on a large-area substrate such as an amorphous glass substrate, the manufacturing cost can be reduced. However, since the gallium nitride layer is formed at a high temperature as described above, it is difficult to directly form the transistor including gallium nitride on the amorphous glass substrate.

An object of an embodiment of the present invention is to provide a semiconductor device using a gallium nitride layer.

### 1. First Embodiment

### [1-1. Configuration of Semiconductor Device 10]

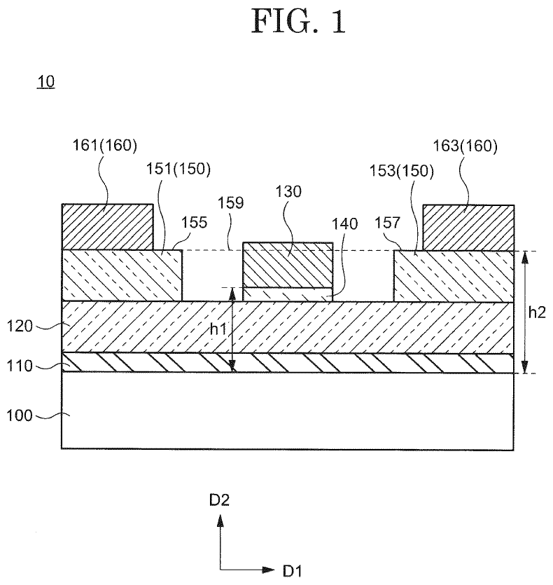

A semiconductor device 10 according to a first embodiment of the present invention will be described with reference to FIG. 1. FIG. 1 is a cross-sectional view showing a configuration of a semiconductor device according to an embodiment of the present invention. As shown in FIG. 1, the semiconductor device 10 includes a substrate 100, an oriented metal layer 110, a first gallium nitride layer 120, a gate electrode 130, a gate insulating layer 140, a second gallium nitride layer 150 (151, 153), and an electrode 160 (161, 163).

The substrate 100 is an amorphous substrate. For example, the substrate 100 is an amorphous glass substrate. However, the substrate 100 may be a resin substrate. As the resin substrate, a flexible substrate such as a polyimide substrate, an acrylic substrate, a siloxane substrate, or a fluororesin substrate is used.

The oriented metal layer 110 is arranged on the substrate 100. The oriented metal layer 110 has a crystal orientation (for example, c-axis orientation). Specifically, a surface of the oriented metal layer 110 is a plane with 6-fold rotational symmetry. For example, the oriented metal layer 110 has a (0001) plane in a hexagonal close-packed structure or a (111) plane in a face-centered cubic structure. For example, titanium or aluminum is used as the oriented metal layer 110. Since the oriented metal layer 110 has the characteristics described above, a gallium nitride layer having high crystallinity can be obtained in the case where the gallium nitride layer is grown on the oriented metal layer 110. For example, in the case where the oriented metal layer 110 is c-axis oriented with respect to the substrate 100, a c-axis oriented gallium nitride layer is grown on the oriented metal layer 110.

For example, the oriented metal layer 110 is formed by a sputtering method. A manufacturing method of the oriented metal layer 110 may be the other physical vapor deposition methods (Physical Vapor Deposition: PVD methods). For example, the oriented metal layer 110 may be formed by a vacuum deposition method or an electron beam deposition method. An underlying insulating layer may be arranged between the substrate 100 and the oriented metal layer 110. As the underlying insulating layer, a silicon oxide layer, a silicon nitride layer, an aluminum oxide layer, an aluminum nitride layer, and a stacked layer thereof are used. For example, a stacked layer of [silicon nitride layer/silicon oxide layer/silicon nitride layer] may be used as the underlying insulating layer.

The first gallium nitride layer 120 is in contact with the oriented metal layer 110 from above the oriented metal layer 110. For example, the first gallium nitride layer 120 is formed by the sputtering method. Crystal growth of the first gallium nitride layer 120 is controlled by the oriented metal layer 110. As a result, the first gallium nitride layer 120 has crystallinity (or orientation) reflecting crystallinity (or orientation) of the oriented metal layer 110. As described above, in the case where the oriented metal layer 110 is c-axis oriented, the c-axis-oriented first gallium nitride layer 120 is obtained.

For example, the first gallium nitride layer 120 is a p-type gallium nitride layer. In this case, for example, a gallium nitride layer doped with magnesium, zinc, cadmium, beryllium, or selenium is used as the first gallium nitride layer 120.

The gate electrode 130 is arranged above the first gallium nitride layer 120 and faces the first gallium nitride layer 120. The gate insulating layer 140 is arranged between the first gallium nitride layer 120 and the gate electrode 130. The gate insulating layer 140 is in contact with each of the first gallium nitride layer 120 and the gate electrode 130. A general metal is used as the gate electrode 130. For example, aluminum, titanium, platinum, nickel, tantalum, and alloys thereof are used as the gate electrode 130 in a single layer or stacked layers. A metal oxide, a metal nitride, or an organic material is used as the gate insulating layer 140. For example, a silicon oxide layer, a silicon nitride layer, an aluminum oxide layer, an aluminum nitride layer, gallium oxide, titanium oxide, titanium nitride, and a stack thereof are used as the gate insulating layer 140. In the case where the semiconductor device 10 is configured to use a Schottky barrier at an interface between the first gallium nitride layer 120 and the gate electrode 130, the gate insulating layer 140 may be omitted.

The second gallium nitride layer 150 is in contact with the first gallium nitride layer 120 from above the first gallium nitride layer 120. The second gallium nitride layer 150 includes a source-side second gallium nitride layer 151 arranged on a source-side of the semiconductor device 10 and a drain-side second gallium nitride layer 153 arranged on a drain-side of the semiconductor device 10. The source-side second gallium nitride layer 151 and the drain-side second gallium nitride layer 153 are separated from each other, and the gate electrode 130 is arranged therebetween. Conductivity of the second gallium nitride layer 150 is higher than conductivity of the first gallium nitride layer 120. That is, electrical resistivity of the second gallium nitride layer 150 is lower than electrical resistivity of the first gallium nitride layer 120.

The second gallium nitride layer 150 is formed by the sputtering method in the same manner as the first gallium nitride layer 120. Crystal growth of the second gallium nitride layer 150 is controlled by the first gallium nitride layer 120. As a result, the second gallium nitride layer 150 has crystallinity (or orientation) reflecting the crystallinity (or orientation) of the first gallium nitride layer 120. As described above, in the case where the first gallium nitride layer 120 is c-axis oriented, the c-axis oriented second gallium nitride layer 150 is obtained.

The second gallium nitride layer 150 is, for example, an n-type gallium nitride layer. In this case, for example, a gallium nitride layer doped with silicon or germanium is used as the second gallium nitride layer 150.

In the present embodiment, although a configuration in which the first gallium nitride layer 120 has p-type conductivity and the second gallium nitride layer 150 has n-type conductivity has been exemplified, the configuration is not limited to this configuration. The first gallium nitride layer 120 may have n-type conductivity, and the second gallium nitride layer 150 may have p-type conductivity. As a representation including the above two configurations, the first gallium nitride layer 120 may have a first conductivity type and the second gallium nitride layer 150 may have a second conductivity type.

As will be described in detail later, the second gallium nitride layer 150 is formed by processing a matrix gallium nitride layer formed on the entire surface thereof. The gate insulating layer 140 and the gate electrode 130 are arranged in a region where the matrix gallium nitride layer is removed by processing the second gallium nitride layer 150. Therefore, the gate insulating layer 140 and the gate electrode 130 are located between the second gallium nitride layers 150 (the source-side second gallium nitride layer 151 and the drain-side second gallium nitride layer 153 in the case of FIG. 1) which face each other in a cross-sectional view. In other words, a distance h1 from a top surface of the substrate 100 to a top surface of the gate insulating layer 140 in the cross-sectional view is smaller than a distance h2 from the top surface of the substrate 100 to a top surface of the second gallium nitride layer 150 in the cross-sectional view. In other words, a line segment 159 connecting a top surface 155 of the source-side second gallium nitride layer 151 and a top surface 157 of the drain-side second gallium nitride layer 153 crosses the gate electrode 130 or the gate insulating layer 140 in the cross-sectional view. In FIG. 1, the line segment 159 crosses the gate insulating layer 140.

Since the first gallium nitride layer 120 and the second gallium nitride layer 150 are formed by the sputtering method, a process gas used in a sputtering process remains in these gallium nitride layers. For example, in the case where argon gas is used in the sputtering process for forming the first gallium nitride layer 120 and the second gallium nitride layer 150, the gallium nitride layers include argon. For example, the argon gas can be detected by analytical methods such as secondary ion-mass spectrometry (SIMS) for these gallium nitride layers.

The electrode 160 is in contact with the second gallium nitride layer 150 from above the second gallium nitride layer 150. The electrode 160 includes a source-side electrode 161 arranged on the source-side of the semiconductor device 10 and a drain-side electrode 163 arranged on the drain-side of the semiconductor device 10. The source-side electrode 161 is connected to the source-side second gallium nitride layer 151. The drain-side electrode 163 is connected to the drain-side second gallium nitride layer 153. A general metal is used as the electrode 160. For example, aluminum, titanium, platinum, nickel, tantalum, and alloys thereof are used as the electrode 160 in a single layer or stacked layers.

When a predetermined voltage (ON voltage) is supplied to the gate electrode 130, carriers are generated in the first gallium nitride layer 120 (channel is formed) in a vicinity of an interface between the first gallium nitride layer 120 and the gate insulating layer 140. In this state, a potential difference is applied between the source-side second gallium nitride layer 151 and the drain-side second gallium nitride layer 153, so that a current flows from the source-side second gallium nitride layer 151 to the drain-side second gallium nitride layer 153 through the channel.

### [1-2. Method for Manufacturing Semiconductor Device 10]

The oriented metal layer 110 is formed on the substrate 100 which is the amorphous glass substrate. For example, the oriented metal layer 110 is formed by sputtering as described above. The first gallium nitride layer 120 and the second gallium nitride layer 150 are formed above the oriented metal layer 110. For example, these gallium nitride layers are formed by the sputtering method. Formation of the oriented metal layer 110, the first gallium nitride layer 120, and the second gallium nitride layer 150 is preferably performed continuously. For example, the formation of these layers may be performed in a sputtering apparatus provided with a plurality of chambers for forming the respective layers while being held in a vacuum. By forming the layer described above in this way, contamination at the interface between the oriented metal layer 110 and the first gallium nitride layer 120, and at the interface between the first gallium nitride layer 120 and the second gallium nitride layer 150 can be reduced by forming the layer described above, and defects in the first gallium nitride layer 120 and the second gallium nitride layer 150 can be reduced. As a result, good crystallinity can be obtained for each of the first gallium nitride layer 120 and the second gallium nitride layer 150.

Subsequently, as shown in FIG. 1, the second gallium nitride layer 150 formed later in a region where the gate electrode 130 and the gate insulating layer 140 are arranged is removed, and the first gallium nitride layer 120 in the region is exposed.

Subsequently, the gate insulating layer 140 and the gate electrode 130 are formed. The gate insulating layer 140 and the gate electrode 130 are formed on each of the first gallium nitride layer 120 and the second gallium nitride layer 150. Thereafter, as shown in FIG. 1, the gate insulating layer 140 and the gate electrode 130 are patterned. Subsequently, the electrode 160 is formed on an entire surface and patterned as shown in FIG. 1.

As described above, since the oriented metal layer 110, the first gallium nitride layer 120, and the second gallium nitride layer 150 are continuously formed, the first gallium nitride layer 120 and the second gallium nitride layer 150 having good crystallinity can be obtained. As a result, good electrical property of the semiconductor device 10 can be obtained.

Although a manufacturing method in which the electrode 160 is formed after the gate insulating layer 140 and the gate electrode 130 are patterned has been exemplified above, the manufacturing method is not limited to this manufacturing method. For example, the electrode 160 may be formed immediately after the second gallium nitride layer 150 is formed, and the gate insulating layer 140 and the gate electrode 130 may be patterned after the patterning of the electrode 160 and 15 the patterning of the second gallium nitride layer 150 are performed.

[1-3. Method for Depositing First Gallium Nitride Layer 120 and Second Gallium Nitride Layer 150]20) Deposition of the gallium nitride layer using sputtering will be described.

The substrate 100 such as the amorphous glass substrate is disposed in a vacuum chamber of the sputtering apparatus at a position facing a gallium nitride target. Composition ratio of gallium nitride in the gallium nitride target is preferably 0.7 or more and 2 or less in terms of ratio of gallium to nitrogen. The vacuum chamber is supplied with nitrogen gas in addition to a sputtering gas (such as argon or krypton). In this case, the composition ratio of gallium nitride in the gallium nitride target is preferably a gallium-rich ratio over nitrogen. For example, the nitrogen may be supplied by a nitrogen radical source. A sputtering power supply may be a DC power supply, an RF power supply, or a pulsed DC power supply.

The substrate 100 may be heated in the vacuum chamber. For example, the substrate 100 may be heated at a room temperature or more and less than 600° C., preferably 100° C. or more and 400° C. or less. At this heating temperature, a heat treatment can be applied to an amorphous glass substrate having low heat resistance. This heating temperature is lower than the heating temperature of the metal organic vapor deposition (MOCVD) or the hydride vapor phase epitaxy (HVPE).

The sputtering gas is supplied after the vacuum chamber in which the substrate 100 is arranged is sufficiently evacuated. A gallium nitride layer is formed by applying a voltage between the substrate 100 and the gallium nitride target at a predetermined pressure to generate a plasma.

The configuration of the sputtering apparatus or sputtering conditions can be appropriately changed. An aluminum gallium nitride layer can be formed if an aluminum gallium nitride target is used instead of the gallium nitride target.

### 2. Second Embodiment

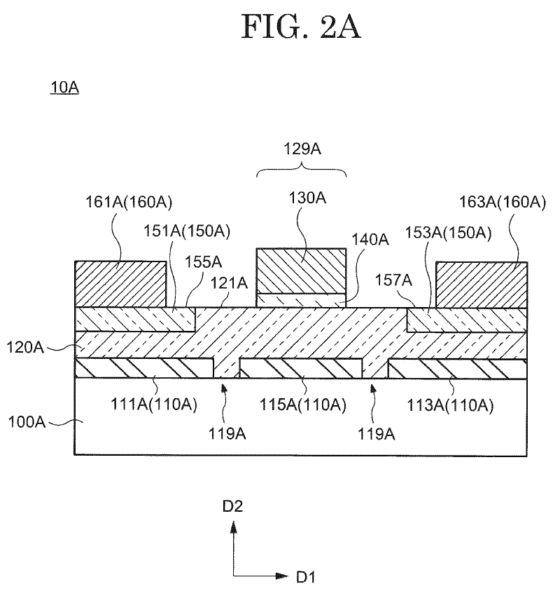

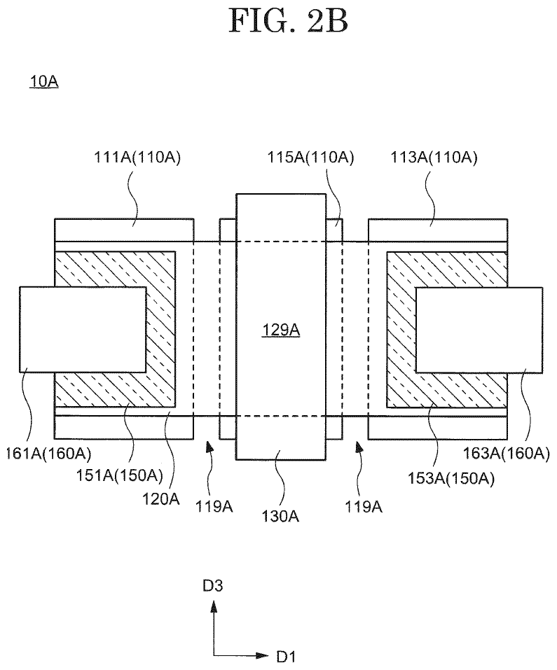

Referring to FIG. 2A and FIG. 2B, a semiconductor device 10A according to a second embodiment of the present disclosure will be described. The semiconductor device 10A is similar to the semiconductor device 10 according to the first embodiment. Descriptions of the same configuration as that of the semiconductor device 10 of the first embodiment in a configuration of the semiconductor device 10A are omitted, and differences from the semiconductor device 10 will be mainly described in the following description. In the case of describing the same configuration as in the first embodiment in the following explanation, with reference to FIG. 1, the letter “A” is added after the reference signs shown in FIG. 1.

### [2-1. Configuration of Semiconductor Device 10A]

As shown in FIG. 2A, an oriented metal layer 110A includes a first oriented metal layer 111A, a second oriented metal layer 113A, and a third oriented metal layer 115A. The first oriented metal layer 111A, the second oriented metal layer 113A, and the third oriented metal layer 115A are separated from each other by a separating portion 119A. In the present embodiment, a first gallium nitride layer 120A is embedded in a region where a pattern of the oriented metal layer 110A is not present in the separating portion 119A. Even in the state where the ON voltage is supplied to a gate electrode 130A, the first gallium nitride layer 120A in the separating portion 119A has a higher resistivity than the oriented metal layer 110A.

As shown in FIG. 2B, the separating portion 119A extends in a direction D3 crossing a direction of a current flowing in the semiconductor device 10A. The separating portion 119A crosses the first gallium nitride layer 120A in the direction D3 between a source-side second gallium nitride layer 151A and a drain-side second gallium nitride layer 153A. That is, the separating portion 119A suppresses a current supplied to the source-side second gallium nitride layer 151A from flowing to the drain-side second gallium nitride layer 153A via the oriented metal layer 110A.

Referring to FIG. 2B, the first oriented metal layer 111A overlaps the source-side second gallium nitride layer 151A in a plan view. Similarly, the second oriented metal layer 113A overlaps the drain-side second gallium nitride layer 153A in a plan view. Referring to FIG. 2A and FIG. 2B, the third oriented metal layer 115A overlaps the first gallium nitride layer 120A in a region between the source-side second gallium nitride layer 151A and the drain-side second gallium nitride layer 153A in a plan view. More specifically, a region (channel region 129A) where the first gallium nitride layer 120A and the gate electrode 130A overlap is arranged inside the third oriented metal layer 115A in a plan view.

As described above, although the configuration in which the first gallium nitride layer 120A is arranged in the separating portion 119A has been exemplified, the present embodiment is not limited to this configuration. An insulator such as a metal oxide may be embedded in the separating portion 119A, and the first oriented metal layer 111A, the second oriented metal layer 113A, and the third oriented metal layer 115A may be insulated from each other. Alternatively, the oriented metal layer in the region corresponding to the separating portion 119A may be made higher in resistivity or insulated by oxidizing the oriented metal layer 110A in the region corresponding to the separating portion 119A.

In the present embodiment, although a configuration in which the second gallium nitride layer 150A is formed so as to be embedded in the first gallium nitride layer 120A, and a top surface 121A of the first gallium nitride layer 120A and top surfaces 155A and 157A of the second gallium nitride layer 150A are at substantially the same position in a direction D2 is exemplified, the configuration is not limited to this configuration. For example, the second gallium nitride layer 150 may be arranged on the first gallium nitride layer 120 as shown in FIG. 1.

As described in the first embodiment, since the oriented metal layer 110A is arranged below the first gallium nitride layer 120A, the first gallium nitride layer 120A having good crystallinity can be obtained. On the other hand, since the oriented metal layer 110A has higher conductive property than the first gallium nitride layer 120A, a leakage current may flow from the source-side second gallium nitride layer 151A to the drain-side second gallium nitride layer 153A via the oriented metal layer 110A. Even in such cases, the leakage current can be suppressed by separating at least the first oriented metal layer 111A and the second oriented metal layer 113A by the separating portion 119A.

As described above, the source-side second gallium nitride layer 151A having good crystallinity can be obtained by overlapping the first oriented metal layer 111A and the source-side second gallium nitride layer 151A in a plan view. Similarly, the drain-side second gallium nitride layer 153A having good crystallinity can be obtained by overlapping the second oriented metal layer 113A and the drain-side second gallium nitride layer 153A in a plan view. Similarly, the first gallium nitride layer 120A having good crystallinity in the channel region 129A can be obtained by overlapping the third oriented metal layer 115A and the first gallium nitride layer 120A corresponding to the channel region 129A in a plan view.

### [2-2. Modification of Semiconductor Device 10A]

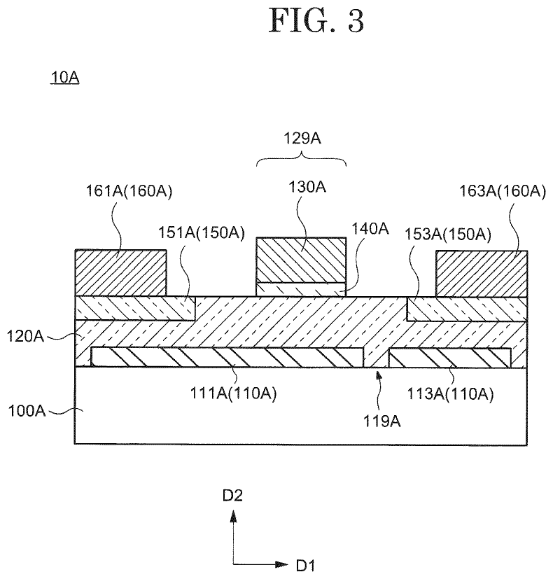

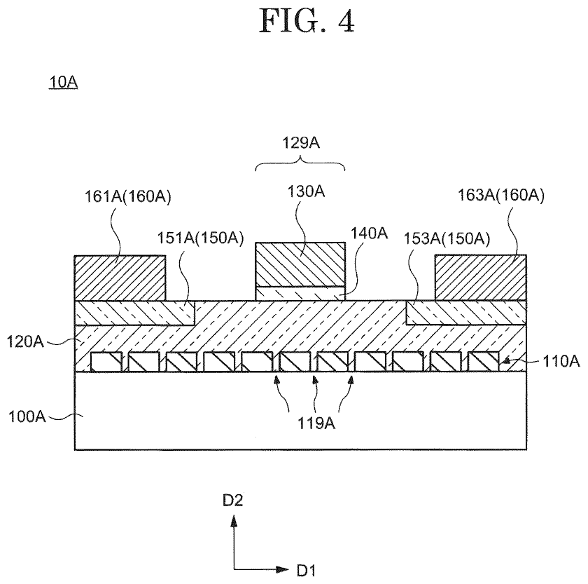

FIG. 3 and FIG. 4 show modifications of the semiconductor device 10A according to the second embodiment. In the embodiment shown in FIG. 3, only one separating portion 119A is arranged between the first oriented metal layer 111A and the second oriented metal layer 113A. The separating portion 119A is arranged between the gate electrode 130A and the drain-side second gallium nitride layer 153A in a plan view, and the first oriented metal layer 111A overlaps the source-side second gallium nitride layer 151A and the gate electrode 130A. The first gallium nitride layer 120A having good crystallinity can be obtained in the channel region 129A by providing the separating portion 119A at the position described above. As a result, a good electrical property of the semiconductor device 10A can be obtained.

In the case where only one separation unit 119A is arranged, the position of the separation unit 119A is not limited to the configuration described above. As described above, as long as the leakage current flowing from the source-side second gallium nitride layer 151A to the drain-side second gallium nitride layer 153A can be suppressed, the separating portion 119A can be arranged at any position.

In the embodiment shown in FIG. 4, the number of the separation units 119A is larger than the number of the separation units 119 shown in FIG. 3. As shown in FIG. 4, the separating portion 119A may be arranged in a region overlapping the channel region 129A, the source-side second gallium nitride layer 151A, and the drain-side second gallium nitride layer 153A. The oriented metal layers 110A may be separated in a lattice shape by the separating portion 119A. The size, shape, and number of the separating portions 119A can be appropriately changed in the channel region 129A, the region immediately below the electrode 160A, and the region between the channel region 129A and the electrode 160A. Positions at which a plurality of separating portions 119A are arranged may be equally spaced, or may be irregular. The crystallinity required for the first gallium nitride layer 120A and an interval between the separating portions 119A may be different depending on the required electrical property for semiconductor device 10A.

### 3. Third Embodiment

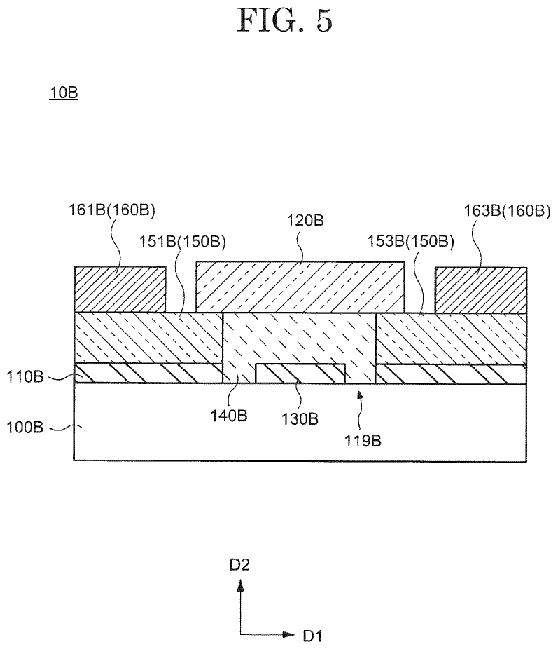

Referring to FIG. 5, a semiconductor device 10B according to a third embodiment of the present disclosure will be described. The semiconductor device 10B is similar to the semiconductor device 10A according to the second embodiment. In the following description, differences from the semiconductor device 10A in a configuration of the semiconductor device 10B will be mainly described. In the following description, in the case of describing the same configuration as in the embodiments described above in the following explanation, with reference to FIG. 1, the letter “B” is added after the reference signs shown in FIG. 1.

### [3-1. Configuration of Semiconductor Device 10B]

As shown in FIG. 5, an oriented metal layer 110B and a gate electrode 130B are arranged on a substrate 100B. The oriented metal layer 110B and the gate electrode 130B are separated by a separating portion 119B. A second gallium nitride layer 150B is arranged on the oriented metal layer 110B. A gate insulating layer 140B is arranged on the gate electrode 130B. The gate insulating layer 140B are arranged so as to fill the separating portion 119B. A first gallium nitride layer 120B is arranged on the gate insulating layer 140B and the second gallium nitride layer 150B. The second gallium nitride layer 150B is in contact with the oriented metal layer 110B. The gate insulating layer 140B is in contact with the gate electrode 130B. The first gallium nitride layer 120B is in contact with the second gallium nitride layer 150B and the gate insulating layer 140B. In other words, the gate electrode 130B and the gate insulating layer 140B are arranged between the first gallium nitride layer 120B and the substrate 100B. The second gallium nitride layer 150B is arranged between the oriented metal layer 110B and the first gallium nitride layer 120B.

In the present embodiment, the gate electrode 130B and the gate insulating layer 140B have crystal orientations same as the oriented metal layer 110B. The gate electrode 130B may be the same layer as the oriented metal layer 110B. In other words, the gate electrode 130B and the oriented metal layer 110B may have the same material and film thickness.

According to the semiconductor device 10B of the present embodiment, since the separating portion 119B is arranged between the oriented metal layer 110B and a source-side second gallium nitride layer 151B, the leakage current can be suppressed as in the semiconductor device 10A of the second embodiment. Since the gate electrode 130B is formed of the same layer as the oriented metal layer 110B, the process for forming the gate electrode can be omitted.

### 4. Fourth Embodiment

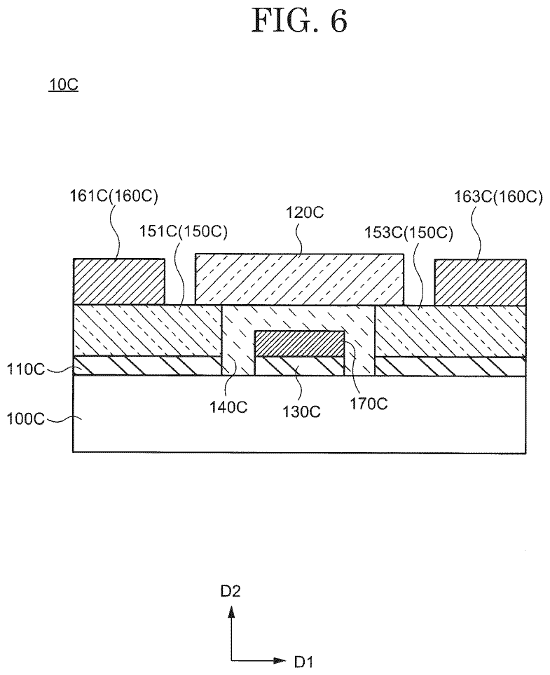

Referring to FIG. 6, a semiconductor device 10C according to a fourth embodiment of the present disclosure will be described. The semiconductor device 10C is similar to the semiconductor device 10B according to the third embodiment. In the following explanation, differences from the semiconductor device 10B in a configuration of the semiconductor device 10C will be mainly described. In the following description, in the case of describing the same configuration as in the embodiments described above in the following explanation, with reference to FIG. 1, the letter “C” is added after the reference signs shown in FIG. 1.

### [4-1. Configuration of Semiconductor Device 10C]

As shown in FIG. 6, a third gallium nitride layer 170C is arranged between a gate electrode 130C and a gate insulating layer 140C. Conductive property of the third gallium nitride layer 170C is higher than conductive property of a first gallium nitride layer 120C. That is, the third gallium nitride layer 170C has a lower resistivity than the first gallium nitride layer 120C. The conductive property of the third gallium nitride layer 170C is higher than conductive property of the second gallium nitride layer 150C. That is, the third gallium nitride layer 170C has a lower resistivity than the second gallium nitride layer 150C.

In the case where the gate electrode 130C is formed in the same layer as an oriented metal layer 110C, a film thickness thereof may be limited. For example, in order to obtain the oriented metal layer 110C having a good orientation, an upper limit may be provided for the film thickness of the oriented metal layer 110C. If the upper limit of the film thickness of the oriented metal layer 110C is limited, electric resistivity of the gate electrode 130C is also limited. Therefore, properties necessary for a circuit operation may not be obtained in some cases.

In such cases, a stacked structure of the gate electrode 130C and the third gallium nitride layer 170C can be used as the gate electrode by providing the third gallium nitride layer 170C on the gate electrode 130C. Therefore, it is possible to reduce electrical resistance of the gate electrode of the stacked structure.

### 5. Fifth Embodiment

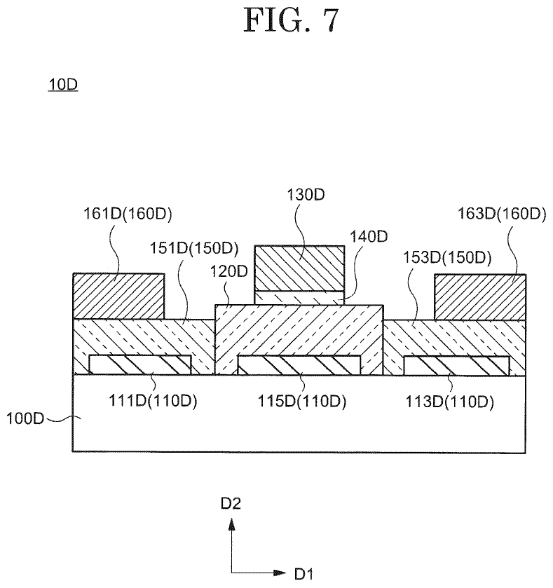

Referring to FIG. 7, a semiconductor device 10D according to a fifth embodiment of the present disclosure will be described. The semiconductor device 10D is similar to the semiconductor device 10A according to the second embodiment. In the following explanation, differences from the semiconductor device 10A in a configuration of the semiconductor device 10D will be mainly described. In the following description, in the case of describing the same configuration as in the embodiments described above in the following explanation, with reference to FIG. 1, the letter “D” is added after the reference signs shown in FIG. 1.

### [5-1. Configuration of Semiconductor Device 10D]

As shown in FIG. 7, a first gallium nitride layer 120D arranged on a third oriented metal layer 115D is patterned. A first oriented metal layer 111D and a second oriented metal layer 113D are arranged in region from which the first gallium nitride layer 120D is removed. A second gallium nitride layer 150D is arranged on the first oriented metal layer 111D and the second oriented metal layer 113D. The first gallium nitride layer 120D is in contact with the third oriented metal layer 115D. A source-side second gallium nitride layer 151D is in contact with the first oriented metal layer 111D. A drain-side second gallium nitride layer 153D is in contact with the second oriented metal layer 113D.

As described above, since both the first gallium nitride layer 120D and the second gallium nitride layer 150D are in contact with the oriented metal layer 110D, a gallium nitride layer having good crystallinity can be obtained.

### [5-2. Modification of Semiconductor Device 10D]

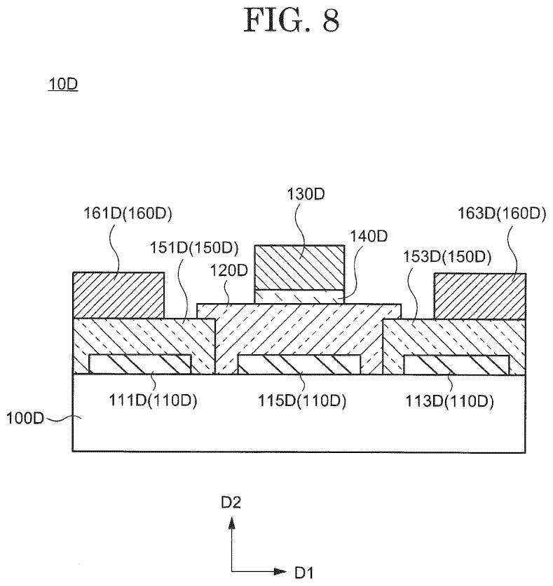

FIG. 8 to FIG. 10 show modifications of the semiconductor device 10D. The same effects as those of the semiconductor device 10D described above can also be obtained in the following modification.

In the modification shown in FIG. 8, the first gallium nitride layer 120D rides on the second gallium nitride layer 150D. That is, the first gallium nitride layer 120D is formed on a part of a top surface of the second gallium nitride layer 150D. For example, the second gallium nitride layer 150D is first formed after the oriented metal layer 110D is formed, and then the first gallium nitride layer 120D is formed, whereby the configuration shown in FIG. 8 can be obtained.

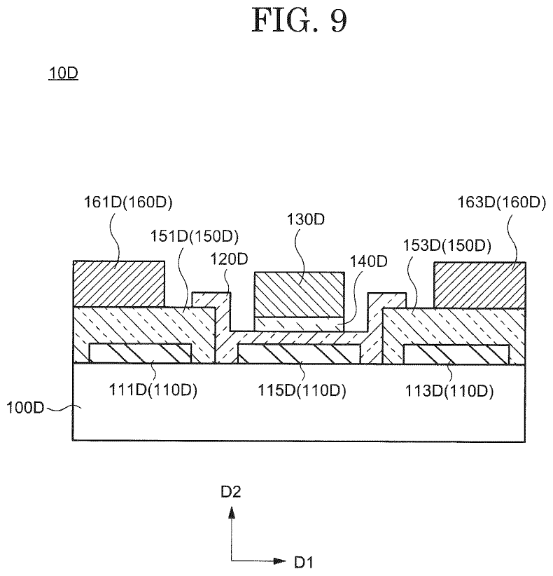

In the modification shown in FIG. 9, the first gallium nitride layer 120D is formed on a part of the top surface of the second gallium nitride layer 150D as in FIG. 8. On the other hand, a recess is formed on a top surface of the first gallium nitride layer 120D in a region corresponding to the third oriented metal layer 115D unlike FIG. 8. The gate insulating layer 140D and the gate electrode 130D are arranged in the recess.

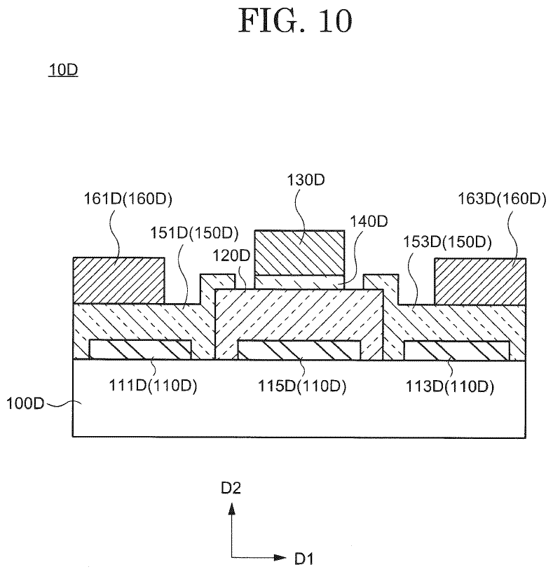

In the modification shown in FIG. 10, the second gallium nitride layer 150D rides on the first gallium nitride layer 120D. That is, the second gallium nitride layer 150D is formed on a part of the top surface of the first gallium nitride layer 120D. For example, the first gallium nitride layer 120D is first formed after the oriented metal layer 110D is formed, and then the second gallium nitride layer 150D is formed, whereby the configuration shown in FIG. 10 can be obtained.

### 6. Sixth Embodiment

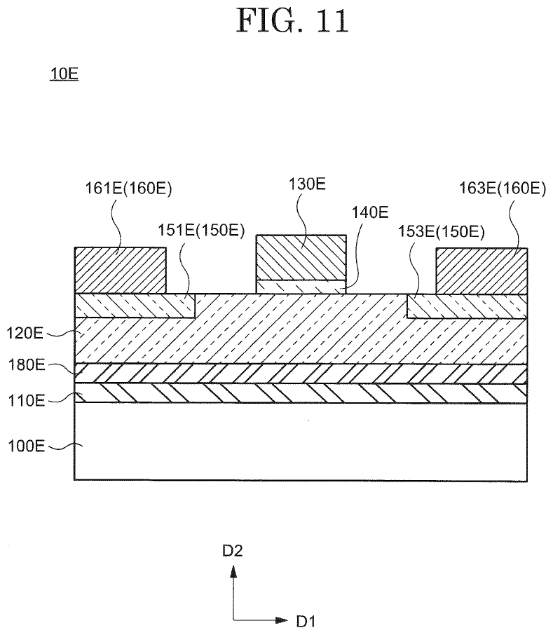

Referring to FIG. 11, a semiconductor device 10E according to a sixth embodiment of the present disclosure will be described. The semiconductor device 10E is similar to the semiconductor device 10A according to the second embodiment. In the following explanation, differences from the semiconductor device 10A in a configuration of the semiconductor device 10E will be mainly described. In the following description, in the case of describing the same configuration as in the embodiments described above in the following explanation, with reference to FIG. 1, the letter “E” is added after the reference signs shown in FIG. 1.

### [6-1. Configuration of Semiconductor Device 10E]

As shown in FIG. 11, an oriented insulating layer 180E is arranged between an oriented metal layer 110E and a first gallium nitride layer 120E. The oriented insulating layer 180E is in contact with the oriented metal layer 110E and the first gallium nitride layer 120E. The oriented insulating layer 180E has crystal orientation (for example, c-axis orientation). Specifically, a surface of the oriented insulating layer 180E is a surface having 6-fold rotational symmetry. For example, the oriented insulating layer 180E has a (0001) plane in a hexagonal close-packed structure or a (111) plane in a face-centered cubic structure. For example, aluminum nitride, gallium oxide, titanium nitride, or titanium oxide is used as the oriented insulating layer 180E. The oriented insulating layer 180E is formed by the sputtering method in the same manner as the oriented metal layer 110E. However, the oriented insulating layer 180E may be formed by the other methods like the PVD method or the CVD method.

The oriented insulating layer 180E is in contact with the oriented metal layer 110E, so that the oriented insulating layer 180E having a better orientation than an oriented insulating layer formed on a layer having no orientation can be obtained. Further, the first gallium nitride layer 120E having good crystallinity can be obtained by the first gallium nitride layer 120E being in contact with the oriented insulating layer 180E. Further, since the oriented metal layer 110E and the first gallium nitride layer 120E are electrically insulated from each other by the oriented insulating layer 180E, a leakage current flowing from a source-side second gallium nitride layer 151E to a drain-side second gallium nitride layer 153E via the oriented metal layer 110E can be suppressed. In the case where the oriented insulating layer 180E is arranged, the oriented metal layer 110E may be omitted.

### 7. Seventh Embodiment

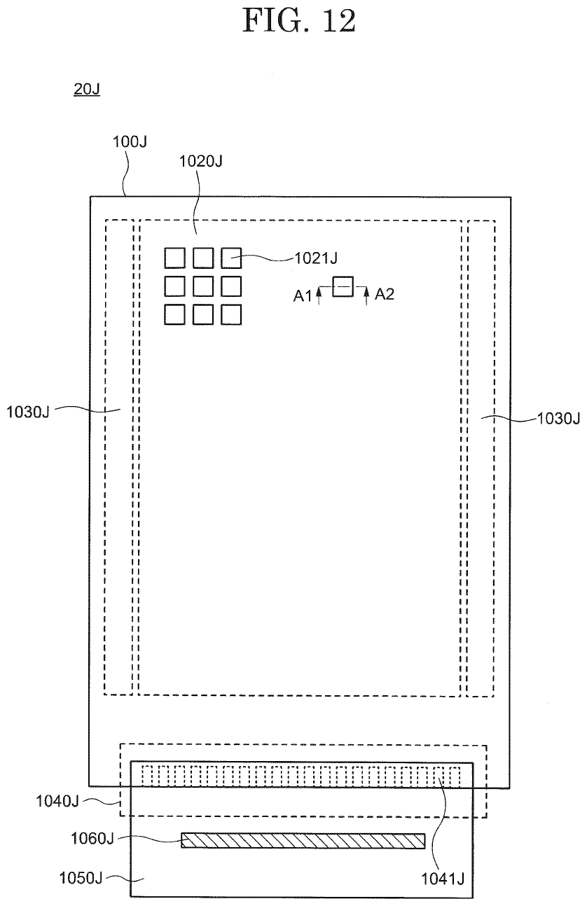

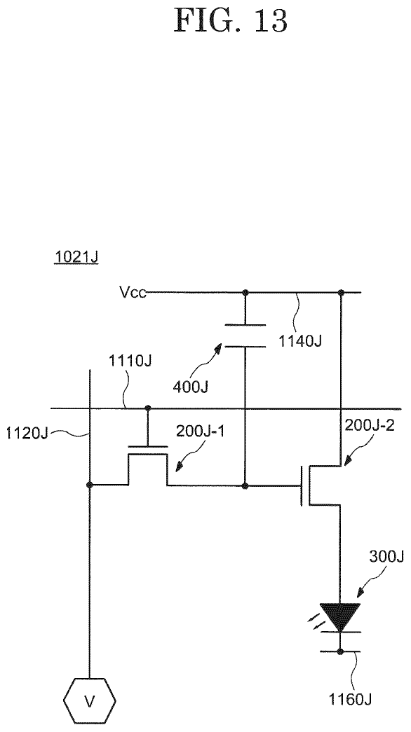

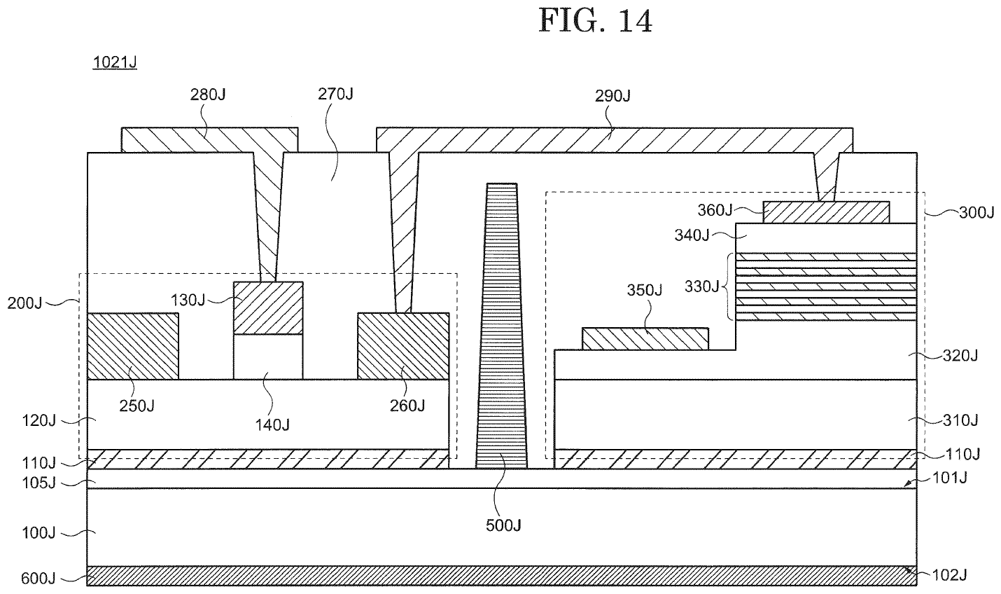

Referring to FIG. 12 to FIG. 14, a display device 20J according to a seventh embodiment of the present disclosure will be described. FIG. 12 is a schematic diagram showing a configuration of a display device according to an embodiment of the present invention. FIG. 13 is a circuit diagram (pixel circuit) of a pixel of a display device according to an embodiment of the present invention. FIG. 14 is a cross-sectional view of a pixel of a display device according to an embodiment of the present invention.

### [7-1. Outline of Display Device 20J Configuration]

FIG. 12 is a schematic diagram showing a configuration of the display device 20J according to an embodiment of the present disclosure. The display device 20J includes a display unit 1020J, a drive circuit unit 1030J, and a terminal unit 1040J on a substrate 100J. The drive circuit unit 1030J is arranged around the display unit 1020J and controls the display unit 1020J. The drive circuit unit 1030J includes, for example, a scan drive circuit and the like. The terminal unit 1040J is arranged at an end portion of the substrate 100J, and supplies an external signal and power to the display device 20J. The terminal unit 1040J includes, for example, a terminal 1041J. The terminal 1041J is connected to a flexible printed circuit board 1050J. A driver IC 1060J is arranged on the flexible printed circuit board 1050J.

The display unit 1020J may display an image or a video, and includes a plurality of pixels 1021J arranged in a matrix. However, an arrangement of the plurality of pixels 1021J are not limited to the matrix. For example, the plurality of pixels 1021J may be arranged in a staggered manner.

### [7-2. Configuration of Pixel 1021J]

FIG. 13 is a circuit diagram (pixel circuit) of the pixel 1021J of the display device 20J according to an embodiment of the present disclosure. The pixel 1021J includes a first transistor 200J-1, a second transistor 200J-2, a light-emitting diode 300J, and a capacitive element 400J.

The first transistor 200J-1 functions as a selection transistor. That is, a conduction of the first transistor 200J-1 is controlled by a scanning line 1110J. In the first transistor 200J-1, a gate, a source, and a drain are electrically connected to the scanning line 1110J, a signal line 1120J, and a gate of the second transistor 200J-2, respectively.

The second transistor 200J-2 functions as a driving transistor. That is, the second transistor 200J-2 controls emission brightness of the light-emitting diode 300J. In the second transistor 200J-2, the gate, a source, and a drain are electrically connected to the drain of the first transistor 200J-1, a drive power supply line 1140J, and an anode (p-type electrode) of the light-emitting diode 300J, respectively.

One of the capacitance electrodes of the capacitive element 400J is electrically connected to the gate of the second transistor 200J-2 and the drain of the first transistor 200J-1. The other capacitance electrode of the capacitive element 400J is electrically connected to the drive power supply line 1140J.

The anode of the light-emitting diode 300J is connected to the drain of the second transistor 200J-2. A cathode (n-type electrode) of the light-emitting diode 300J is connected to a reference power supply line 1160J.

### [7-3. Cross-sectional Structure of Display Device 20J]

A layer configuration of the pixel 1021J will be described referring to FIG. 14. The first transistor 200J-1 and the second transistor 200J-2 are not particularly distinguished from each other and are explained as a transistor 200J in the explanation of FIG. 14.

FIG. 14 is a cross-sectional view of the pixel 1021J taken along a line A1-A2 shown in FIG. 12. As shown in FIG. 14, the display device 20J includes the substrate 100J, an underlayer 105J, an oriented metal layer 110J, the transistor 200J, the light-emitting diode 300J, a light-shielding wall 500J, a light-shielding layer 600J, an interlayer film 270J, a conductive layer 280J, and a transparent conductive layer 290J. The underlayer 105J, the oriented metal layer 110J, the transistor 200J, the light-emitting diode 300J, the light-shielding wall 500J, the interlayer film 270J, the conductive layer 280J, and the transparent conductive layer 290J are arranged on a first surface 101J side of the substrate 100J. The light-shielding layer 600J is arranged on a second surface 102J side of the substrate 100J opposite to the first surface 101J.

The substrate 100J is a support substrate for the transistor 200J and the light-emitting diode 300J. As the substrate 100J, an amorphous glass substrate or the like can be used as described above.

The underlayer 105J is arranged on the substrate 100J. The underlayer 105J may prevent diffusion of impurities from the substrate 100J or diffusion of impurities from the outside (for example, water, sodium, or the like). For example, a silicon nitride layer or a stack of a silicon oxide layer and a silicon nitride layer may be used as the underlayer 105J.

The oriented metal layer 110J is arranged on the underlying layer 105J. Crystallinity of a first gallium nitride layer 120J of the transistor 200J formed on the oriented metal layer 110J can be improved, and crystallinity of a gallium nitride layer 310J of the light-emitting diode 300J formed on the oriented metal layer 110J can be improved by arranging the oriented metal layer 110J. The first gallium nitride layer 120J and the gallium nitride layer 310J are formed in the same layer and have the same film thickness and physical properties.

In the case where the oriented metal layer 110J includes a nitrogen compound (for example, titanium nitride), the underlayer 105J may not be arranged. Since nitrogen contained in the nitrogen compound described above has a large electronegativity, it is possible to trap the impurities contained in the substrate 100J.

The transistor 200J includes the first gallium nitride layer 120J, a gate electrode 130J, a gate insulating layer 140J, a source electrode 250J, and a drain electrode 260J. For example, the source electrode 250J corresponds to the source-side second gallium nitride layer 151 and the source-side electrode 161 in FIG. 1. For example, the drain electrode 260J corresponds to the drain-side second gallium nitride layer 153 and the drain-side electrode 163 in FIG. 1.

The first gallium nitride layer 120J is arranged on the oriented metal layer 110J. Since the first gallium nitride layer 120J is in contact with the oriented metal layer 110J as described above, crystal growth of the first gallium nitride layer 120J is controlled by the oriented metal layer 110J. Consequently, the first gallium nitride layer 120J is c-axis oriented with respect to the substrate 100J.

Although the transistor 200J is a so-called MOS transistor, the transistor 200J may be a HEMT (High Electron Mobility Transistor).

The light-emitting diode 300J is arranged on the oriented metal layer 110J. The light-emitting diode 300J includes the gallium nitride layer 310J, an n-type semiconductor layer 320J, a light-emitting layer 330J, a p-type semiconductor layer 340J, an n-type electrode 350J, and a p-type electrode 360J.

The gallium nitride layer 310J is arranged on the oriented metal layer 110J. For example, a gallium nitride layer or the like is used as the gallium nitride layer 310J. Since the gallium nitride layer 310J is in contact with the oriented metal layer 110J, crystal growth of the gallium nitride layer 310J is controlled by the oriented metal layer 110J. Consequently, the gallium nitride layer 310J is c-axis oriented with respect to the substrate 100J.

The n-type semiconductor layer 320J is arranged on the gallium nitride layer 310J. For example, a silicon-doped gallium nitride layer or the like is used as the n-type semiconductor layer 320J.

The light-emitting layer 330J is arranged on the n-type semiconducting layer 320J. For example, a stack in which an indium-gallium nitride layer and a gallium nitride layer are alternately stacked is used as the light-emitting layer 330J.

The p-type semiconducting layer 340J is arranged on the light-emitting layer 330J. For example, a magnesium-doped gallium nitride layer is used as the p-type semiconducting layer 340J.

The n-type electrode 350J and the p-type electrode 360J are respectively arranged on the n-type semiconductor layer 320J and the p-type semiconductor layer 340J. For example, a metal such as indium is used as the n-type electrode 350J. For example, a metal such as palladium or gold is used as the p-type electrode 360J.

Although the light-emitting diode 300J may be a so-called micro LED or a mini LED which is deposited and formed by a sputtering method on the substrate 100J which is an amorphous substrate, the light-emitting diode 300J is not limited to those. The micro LED is a LED having a size of 100 micrometers or less on one side. The mini LED is a LED having a size of 100 micrometers or more on one side.

Although not shown in the drawings, a protective layer may be arranged to cover the transistor 200J or the light-emitting diode 300J as needed. A silicon nitride layer or a stacked layer of a silicon oxide layer and a silicon nitride layer may be used as the protective layer.

The light-shielding wall 500J is arranged between the transistor 200J and the light-emitting diode 300J. The light-shielding wall 500J can block light emitted from the light-emitting diode 300J and prevent the transistor 200J from being irradiated with light. For example, an acrylic resin (resin black) to which carbon is added can be used as the light-shielding wall 500J.

The light-shielding layer 600J is arranged on the second surface 102J of the substrate 100J. The light-shielding layer 600J can block light from the outside and prevent the transistor 200J from being irradiated with light. For example, an acrylic resin (resin black) to which carbon is added may be used as the light-shielding layer 600J.

The interlayer film 270J is arranged so as to cover the transistor 200J, the light-emitting diode 300J, and the light-shielding wall 500J. The interlayer film 270J can planarize irregularities formed by the transistor 200J, the light-emitting diode 300J, and the light-shielding wall 500J. For example, an organic insulating film such as an acryl resin film or a polyimide resin film is used as the interlayer film 270J. The interlayer film 270J may be a single layer or a stacked layer. In the case where the interlayer film 270J is a stacked layer, the interlayer film 270J may include not only an organic insulating layer but also an inorganic insulating layer such as a silicon oxide layer or a silicon nitride layer.

The conductive layer 280J and the transparent conductive layer 290J are arranged on the interlayer film 270J. The conductive layer 280J is electrically connected to the gate electrode 130J via an opening arranged in the interlayer film 270J. The transparent conductive layer 290J electrically connects the drain electrode 260J and the p-type electrode 360J via an opening arranged in the interlayer film 270J. The light emitted from the light-emitting layer 330J of the light-emitting diode 300J passes through the transparent conductive layer 290J and is emitted to the outside. For example, a stacked layer of aluminium and titanium (for example, Ti/Al/Ti) can be used as the conductive layer 280J. For example, a transparent conductive layer such as an indium-tin-oxide (ITO) film or an indium-zinc-oxide (IZO) film can be used as the transparent conductive layer 290J.

Each of the embodiments described above as the embodiment of the present invention can be appropriately combined as long as they are not mutually contradictory. The addition, deletion, or design change of components as appropriate, or addition, omission or changes in conditions of processes by those skilled in the art based on each embodiment are also included in the scope of the present invention as long as they are provided with the gist of the present disclosure.

It is understood that, even if the advantageous effect is different from those provided by each of the above-described embodiments, the advantageous effect obvious from the description in the specification or easily predicted by persons ordinarily skilled in the art is apparently derived from the present disclosure.

What is claimed is:

1. A semiconductor device comprising:
an amorphous glass substrate;
an oriented metal layer arranged above the amorphous glass substrate and having a crystal orientation;
a first gallium nitride layer arranged above the oriented metal layer and having a first conductive type;
a second gallium nitride layer arranged above the first gallium nitride layer, connected to the first gallium nitride layer, having higher conductive property than the first gallium nitride layer, including a source-side second gallium nitride layer and a drain-side second gallium nitride layer facing each other, and having a second conductive type;
a gate electrode facing the first gallium nitride layer; and
a gate insulating layer between the first gallium nitride layer and the gate electrode,
wherein the gate insulating layer is positioned between the source-side second gallium nitride layer and the drain-side second gallium nitride layer in a cross-sectional view.

2. The semiconductor device according to claim 1,
wherein a distance from a top surface of the amorphous glass substrate to a top surface of the gate insulating layer is smaller than a distance from the top surface of the amorphous glass substrate to a top surface of the second gallium nitride layer in a cross-sectional view.

3. The semiconductor device according to claim 1,
wherein
the first gallium nitride layer is in contact with the oriented metal layer, and
the second gallium nitride layer and the gate insulating layer are in contact with the first gallium nitride layer.

4. A semiconductor device comprising:
an amorphous glass substrate;
an oriented metal layer arranged above the amorphous glass substrate, including a first oriented metal layer and a second oriented metal layer away from the first oriented metal layer, and having a crystal orientation;
a first gallium nitride layer arranged above the oriented metal layer and having a first conductive type;
a second gallium nitride layer arranged above the oriented metal layer, connected to the first gallium nitride layer, having higher conductive property than the first gallium nitride layer, including a source-side second gallium nitride layer and a drain-side second gallium nitride layer facing each other, and having a second conductive type;
a gate electrode facing the first gallium nitride layer; and
a gate insulating layer between the first gallium nitride layer and the gate electrode,
wherein a portion separating the oriented metal layer and the second oriented metal layer crosses between the source-side second gallium nitride layer and the drain-side second gallium nitride layer in a cross-sectional view.

5. The semiconductor device according to claim 4,
wherein
the first oriented metal layer overlaps the source-side second gallium nitride layer in a plan view, and
the second oriented metal layer overlaps the drain-side second gallium nitride layer in a plan view.

6. The semiconductor device according to claim 4,
wherein
the oriented metal layer further includes a third oriented metal layer away from the first oriented metal layer and the second oriented metal layer,
the first oriented metal layer overlaps the source-side second gallium nitride layer in a plan view,
the second oriented metal layer overlaps the drain-side second gallium nitride layer in a plan view, and
the third oriented metal layer overlaps the first gallium nitride layer between the source-side second gallium nitride layer and the drain-side second gallium nitride layer in a plan view.

7. The semiconductor device according to claim 4,
wherein
the first gallium nitride layer is in contact with the oriented metal layer, and
the second gallium nitride layer is in contact with the first gallium nitride layer from above of the first gallium nitride layer.

8. The semiconductor device according to claim 4,
wherein
the gate electrode is arranged between the first gallium nitride layer and the amorphous glass substrate and has a crystal orientation, and
the gate insulating layer has a crystal orientation.

9. The semiconductor device according to claim 8,
wherein the second gallium nitride layer is arranged between the oriented metal layer and the first gallium nitride layer.

10. The semiconductor device according to claim 8,
wherein
the second gallium nitride layer is in contact with the oriented metal layer,
the gate insulating layer is in contact with the the gate electrode, and
the first gallium nitride layer is in contact with the gate insulating layer.

11. The semiconductor device according to claim 8,
further comprising a third gallium nitride layer arranged between the gate electrode and the gate insulating layer, and having higher conductive property than the second gallium nitride layer.

12. The semiconductor device according to claim 8,
wherein
the oriented metal layer further includes a third oriented metal layer arranged between the first oriented metal layer and the second oriented metal layer, and away from the first oriented metal layer and the second oriented metal layer,
the first gallium nitride layer is in contact with the third oriented metal layer,
the source-side second gallium nitride layer is in contact with the first oriented metal layer,
the drain-side second gallium nitride layer is in contact with the second oriented metal layer, and
the gate electrode is arranged above the first gallium nitride layer.

13. The semiconductor device according to claim 1,
further comprising an oriented insulating layer arranged between the oriented metal layer and the amorphous glass substrate.

14. A semiconductor device comprising:
an amorphous glass substrate;
an oriented metal layer arranged above the amorphous glass substrate and having a crystal orientation;
an oriented insulating layer arranged above the oriented metal layer;
a first gallium nitride layer arranged above the oriented insulating layer and having a first conductive type;
a second gallium nitride layer arranged above the oriented insulating layer, connected to the first gallium nitride layer, having higher conductive property than the first gallium nitride layer, including a source-side second gallium nitride layer and a drain-side second gallium nitride layer facing each other, and having a second conductive type;
a gate electrode facing the first gallium nitride layer; and
a gate insulating layer between the first gallium nitride layer and the gate electrode.

15. The semiconductor device according to claim 14,
wherein the first gallium nitride layer is in contact with the oriented insulating layer.

16. The semiconductor device according to claim 1,
wherein
the oriented metal layer has a plane with 6-fold rotational symmetry.

17. The semiconductor device according to claim 1,
wherein
the oriented metal layer has a (0001) plane in a hexagonal close-packed structure or a (111) plane in a face-centered cubic structure.

18. The semiconductor device according to claim 13,
wherein
the oriented insulating layer has a plane with 6-fold rotational symmetry.

19. The semiconductor device according to claim 13,
wherein
the oriented metal layer has a (0001) plane in a hexagonal close-packed structure or a (111) plane in a face-centered cubic structure.
